(19) United States
(12) Patent Application Publication
(10) Pub. No.: US 2015/0061103 A1
(43) Pub. Date: Mar. 5, 2015

(54) EMBEDDED DIE PACKAGE

(71) Applicants: Texas Instruments Deutschland GMBH, Freising (DE); Texas Instruments Incorporated, Dallas, TX (US)

(72) Inventors: Christopher Daniel Manack, Lantana, TX (US); Frank Stepniak, Allen, TX (US); Anton Winkler, Bavaria (DE)

(73) Assignees: Texas Instruments Deutschland GMBH, Freising (DE); Texas Instruments Incorporated, Dallas, TX (US)

(21) Appl. No.: 14/012,145

(22) Filed: Aug. 28, 2013

(51) Int. Cl. H01L 23/48; H01L 25/00

(52) U.S. Cl. CPC H01L 23/481; H01L 25/50
USPC 257/698; 438/108

(57) ABSTRACT

A method of making an electrical assembly includes making a laminate substrate, embedding a plurality of integrated circuit dies in the laminate substrate, forming a plurality of through-holes in the laminate substrate and adding conductive material to the through-holes, and making at least one saw cut extending through the laminate substrate and through the plurality of through-holes and the conductive material therein to form at least one laminate block with a cut face and a plurality of sectioned through-holes.

### BACKGROUND

An embedded die package has an integrated circuit die embedded in a laminate block with a construction similar to the laminate structure of a printed circuit board. Embedded die packages are often produced in a ball grid array (BGA) format with the BGA positioned at the bottom of the package. Passive components may be connected to the IC die. Such passive components may be positioned on the top of the laminate block or may be embedded in the laminate block. Circuit layers within the laminate block are connected to filled or plated through-holes extending through the laminate block.

Embedded die packages have been produced by a number or companies for several years. One such embedded die package is produced by Texas Instruments Inc., which uses the term “microsystem package” and the trademark “MicroSIP™”in referring to this product. Embedded die packages are described in detail in “Design Summary for MicroSiP™-enabled TPS8267xSiP”, Texas Instruments 1Q 2011 MicroSiP™ Design Summary SLIB006 published 2011, available at www.ti.com, and in “Texas Instruments” Embedded Die Package” by Romain Fraux from Systems Plus Consulting, May 2012, Issue N 23 of 3D Packaging, which are both hereby incorporated by reference for all that is disclosed therein.

### BRIEF DESCRIPTION OF THE DRAWINGS

FIG. 1 is a top plan view of a conventional embedded die package.

FIG. 2 is a schematic cross sectional perspective view of the embedded die package of FIG. 1.

FIG. 3 is a top plan view of an example embodiment of an embedded die package.

FIG. 4 is a schematic cross sectional perspective view of the embedded die package embodiment of FIG. 3.

FIG. 5 is a top front perspective view of the embedded die package of FIGS. 1 and 2 mounted on a printed circuit board.

FIG. 6 is a schematic cross sectional view illustrating the singulation of a substrate having embedded dies therein into a plurality of embedded die packages such as illustrated in FIGS. 2 and 3.

FIG. 7 is a schematic perspective view of the substrate of FIG. 6.

FIG. 8 is a top plan view of a portion of an embedded die substrate with filled through-holes, after singulation thereof.

FIG. 9 is a top plan view of an embedded die substrate with plated through-holes, after singulation thereof.

FIG. 10 is a schematic, bottom perspective view of an example embedded die package having a plurality of filled sectioned through-holes.

FIG. 11 is a flow chart illustrating a method of making an electrical assembly.

### DETAILED DESCRIPTION

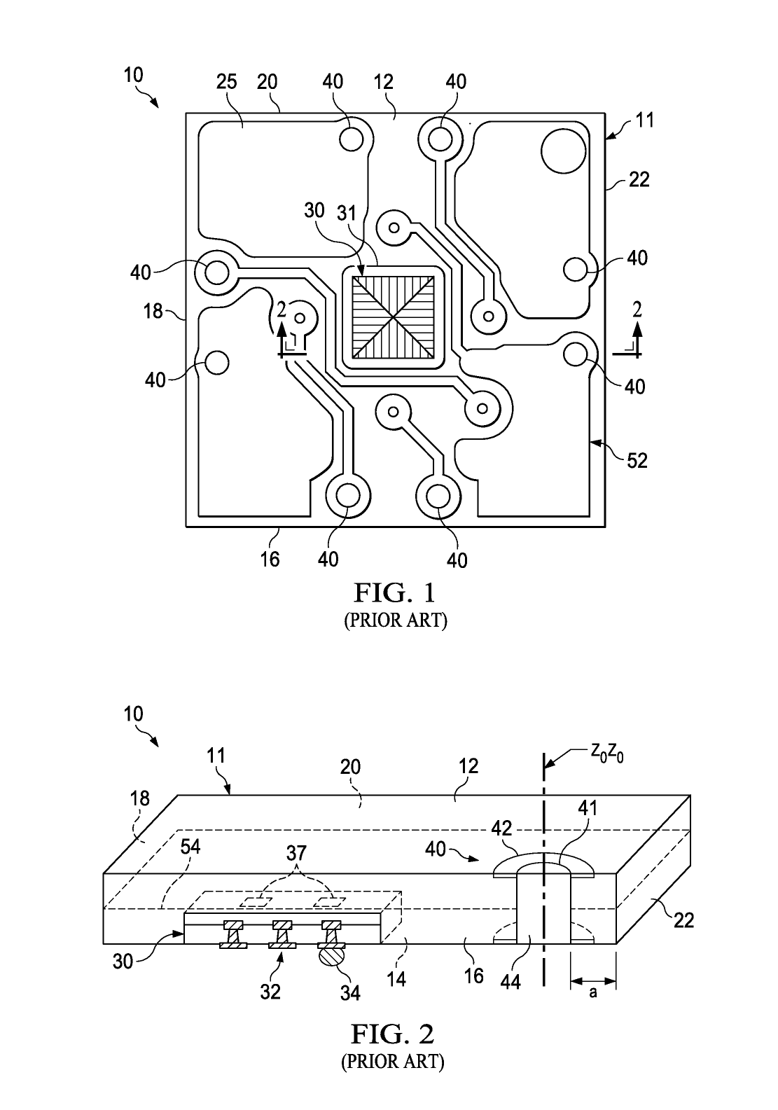

FIG. 1 is a top plan view of a conventional embedded die package 10. The package 10 comprises a rectangular box shaped laminate block 11. The laminate block 11 has a top face 12, bottom face 14, FIG. 2, and a plurality of lateral side faces 16, 18, 20, and 22. An IC die 30 is embedded in the laminate block 11. In this particular embodiment the die 30 is part of a sensor assembly and must have access to the external environment. Thus, the die 30 is positioned within a cavity 31 extending from the top face 12 of the laminate block 11. In another embodiment, in which access to the die 30 from the external environment is not a requirement, no cavity 31 is provided. The IC die 30, as best shown in FIG. 2, comprises a means for electrically connecting the die 30 to an underlying circuit board 200, FIG. 5. One such means may be a ball grid array 32 having a plurality of solder balls 34 (only one shown). The underlying circuit board 200, FIG. 5, has an array of surface contacts (not shown) adapted to be bonded to the balls 34 of the ball grid array 32. The die 30 may also have a plurality of other electrical contacts 37 that may be positioned on a top surface of the die 30.

The laminate block 11 has a plurality of cylindrical through-holes 40 with vertical axes Z₀Z₀. The cylindrical through-holes 40 extend between the top face 12 and bottom face 14 of the laminate block 11. Each through-hole 40, as illustrated in FIG. 2, may be a “filled through-hole” that is filled with conductive material 44, such as copper. The through-holes 40, rather than being filled through-holes, may be “plated through-holes” that have a conductive plating layer applied to the cylindrical side wall of the through-hole 40. The through-holes 40 are set back from an adjacent side face 22 of the laminate block 11. The setback distance “a” must be sufficiently large to prevent cracking of the laminated block 11 in the area between the through-hole 40 and the side face 22. The magnitude of the setback distance “a” directly affects the area of the embedded die package footprint.

The laminate block 11 comprises a plurality of laterally extending circuit layers such as an intermediate circuit layer 54, FIG. 2, which may electrically connect electrical contacts 37 on the integrated circuit die 30 to the conductive filling 44 of the various through-holes 40. One typical circuit configuration 25, which could be provided on a top face of the laminate block 11 or on an intermediate circuit layer of the laminate block 11, is illustrated in FIG. 1.

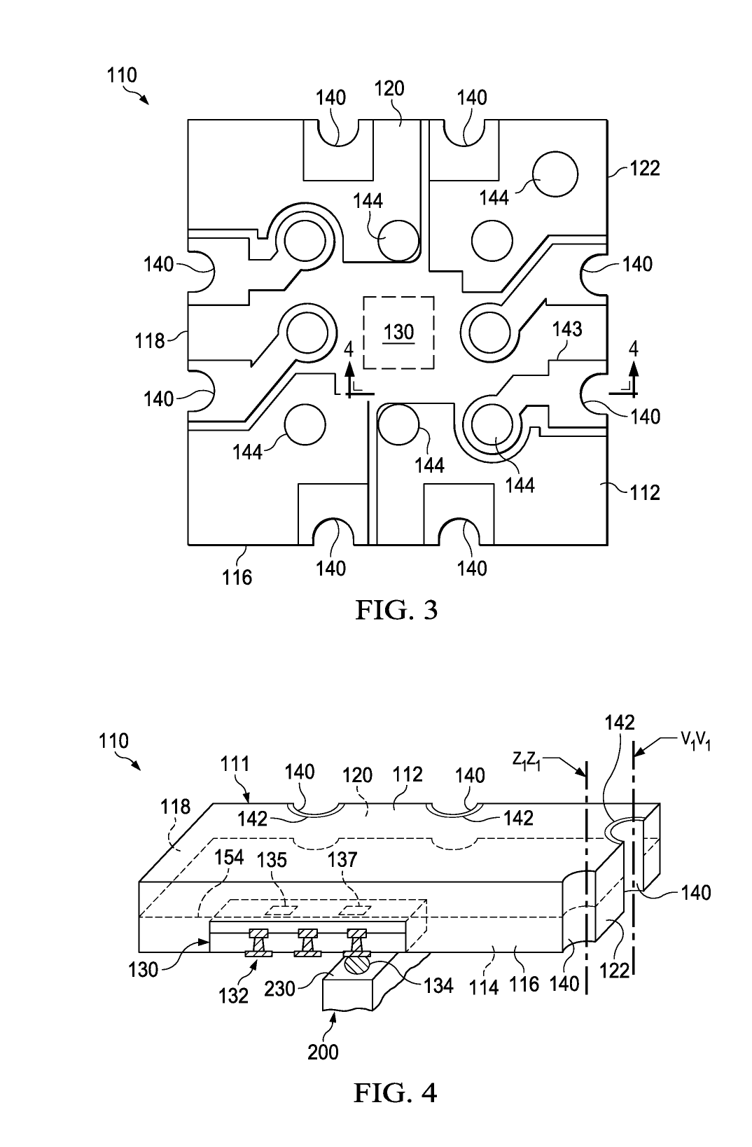

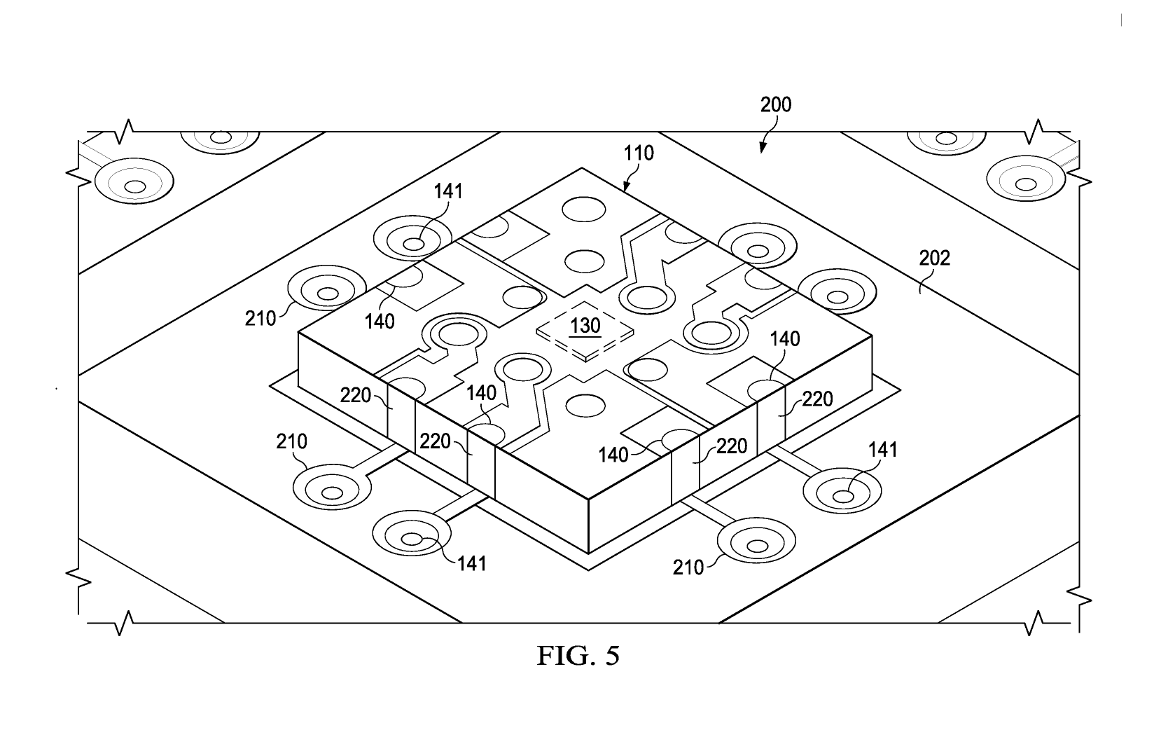

FIG. 3 is a top plan view of an embedded die package 110, according to one example embodiment. The embedded die package 110 comprises a box shaped (regular parallelepiped shaped) laminate block 111 having a plurality of sectioned through-holes 140 positioned about the periphery thereof. FIG. 4 is a schematic cross sectional view of a portion of the embedded die package 110 of FIG. 3. An IC die 130 is embedded in the laminate block 111. The method by which the IC die 130 is embedded in the laminate block 11 may be a conventional method known in the art. The method by which the laminate block 11 is formed may also be a conventional method known in the art.

Unlike the prior art, through-holes 140 are “sectioned through-holes” that have the shape of an axially sectioned/sliced cylinder, i.e., a cylinder sectioned by a cutting plane that extends substantially parallel to its central axis. In some embodiments the sectioned through-holes 140 have a substantially semicircular cross section. The center of curvature of the sectioned through-holes 140 may be positioned in substantial alignment with the adjacent side wall of the block 111, e.g., sidewall 122. The sectioned through-hole 140 may have a plating layer 142 provided on the arcuate surface of the block 111 that defines the sectioned through-hole 140. In addition to sectioned through-holes 140, the block 111 may have a plurality of conventional filled or plated through-holes 144, FIG. 3, (not shown in FIG. 4) positioned inwardly of the periphery of block 111. Some of these conventional through-holes 144 may be connected to one or more of the sectioned through-holes 140 by patterned circuits 143.

The IC die 130 has structure for electrically connecting the die 130 to corresponding contact surfaces 230 of a printed circuit board 200, of which only a broken away portion is shown in FIG. 4. In one embodiment, the electrical connection structure may comprise a ball grid array (BGA) 132 having a plurality of solder balls 134 (only one shown). Ball grid arrays and connection thereof to circuit boards are known in the art. The integrated circuit die 130 may also include a plurality of contact surfaces 135, 137 that are connected as by intermediate laminate layer circuitry 154 to conductive material such as plating 142 provided in the sectioned through-holes 140. Since there is no laminate material positioned outwardly of the sectioned through-hole 140, the problem of laminate breaking and pealing is obviated by this construction. Also, the size of the embedded die package 110 produced by this method may be made smaller than that of a conventional embedded die package having the same sized die.

FIG. 5 is a perspective view of an embedded die package 110 with sectioned through-holes 140 mounted on a printed circuit board 200. The printed circuit board 200 has a plurality of contact surfaces 210 provided on a top face 202 of the circuit board 200. The contact surfaces 210 are arranged around the periphery of the embedded die package 110. The circuit board contact surfaces 210 are electrically connected to the exposed conductive material in the sectioned through-holes 140 (e.g., copper or silver plating or filling). The electrical connection may be provided by conventional solder bonds 220 or other connection material. The large exposed surface of the conductive material, both at the top and sidewall of the laminate block 111 provides better solder wetting than the prior art structure and improves the quality of the solder bond and the reliability of the resulting circuit board/embedded die package assembly 200/110. The ball grid array or other bottom contact surfaces 132 of the die 130 are connected to oppositely positioned contact surfaces 230 on the circuit board 200, as shown in FIG. 4. Such connections are conventional and known in the art. The circuit board 200 may be a conventional printed circuit board or wiring board or interposer or other electrical connection board.

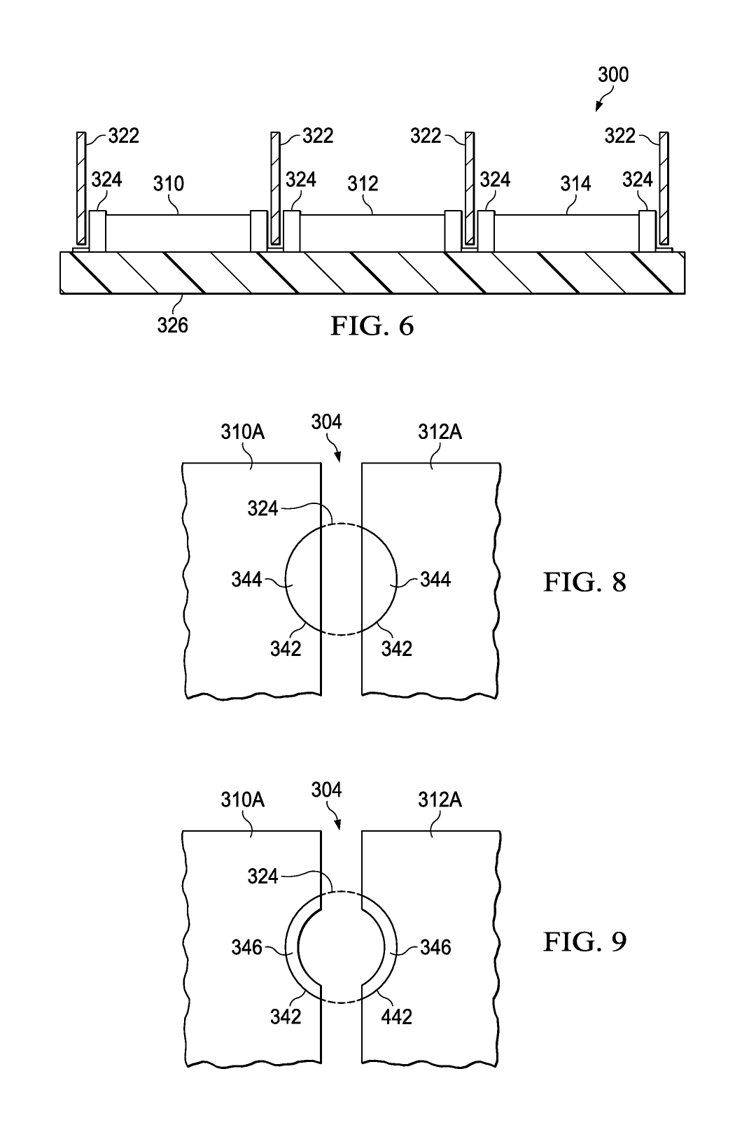

The manner by which an embedded die package 110 with sectioned through-holes 140 is produced will now be described with reference to FIGS. 6-9. Initially cylindrical through-holes 324 are bored through the substrate 300 at predetermined locations associated with edge portions of laminated blocks 310, 312 that are to be formed from the substrate 300. The hole boring may be done with conventional drills in a conventional manner known in the art. After boring the cylindrical through-holes 324, the through-holes 324 may be filled with conductive material such as copper or the like in a conventional manner known in the art. Alternatively, the through-holes 324 may be plated with conductive material, as is also known in the art. The embodiment illustrated in FIG. 8 illustrates an embodiment in which the through-hole 324 has been filled with conductive material 344. FIG. 9 illustrates an embodiment in which the conductive material is a plating layer 346. Two sectioned through-holes 342, FIGS. 8 and 9, are produced in adjacent laminate blocks, e.g., 310, 312 from the cylindrical through-hole 324 as a result of singulation.

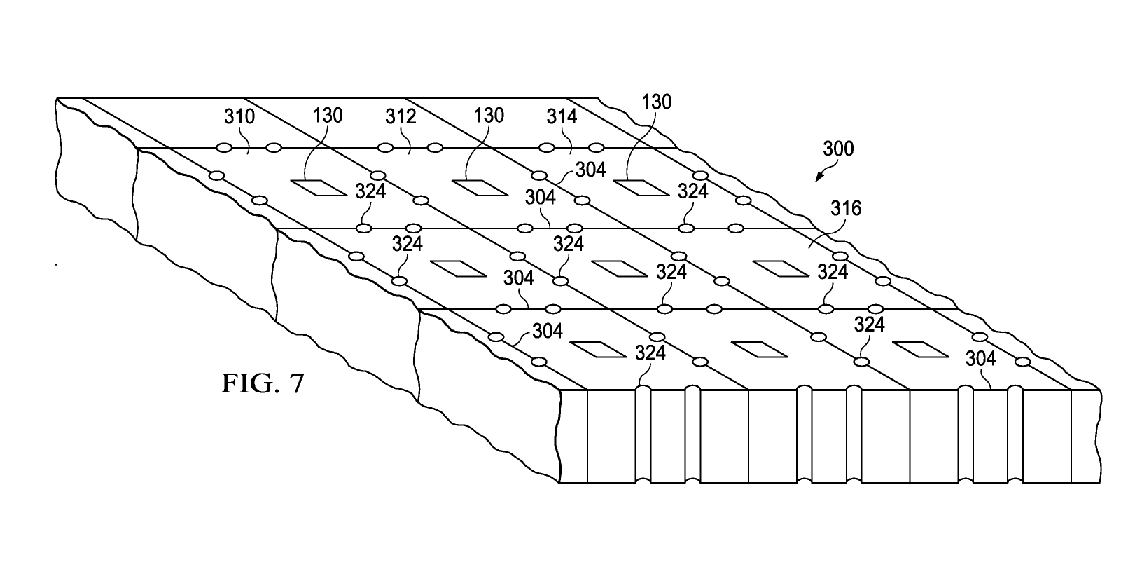

As illustrated by FIGS. 6 and 7, the laminated substrate 300 is constructed in a grid pattern of integrally formed rectangular block portions, e.g., 310, 312, 314, 316, etc. The rectangular block portions are substantially identical. Each block portion comprises a plurality of circuit layers, such as 154, and has an IC die, such as die 130, embedded therein. The grid pattern defines a plurality of saw streets 304, FIG. 7. Cylindrical through-holes 324 are positioned in alignment along each saw street 304.

Next, the substrate 300 is provided with a backing of conventional saw tape 326, FIG. 6, and is moved to a conventional sawing station. At the sawing station a plurality of saw cuts are made along the saw streets 304. The saw streets 304 each intersect a plurality of aligned through-holes 324. The through-holes prior to singulation are represented in dashed and solid lines in FIGS. 8 and 9. FIGS. 8 and 9 are top plan views of adjacent embedded die packages 310A, 312A formed from the substrate 300. The saw singulation produces a plurality of substantially identical embedded die packages 310A, 312A, etc. that correspond to substrate 300 portions 310, 312, etc. In other embodiments, rather than saw singulation, the various substrate portions 310, 312, etc., may be singulated by laser singulation or by die stamping or by any other singulation method now known or later developed.

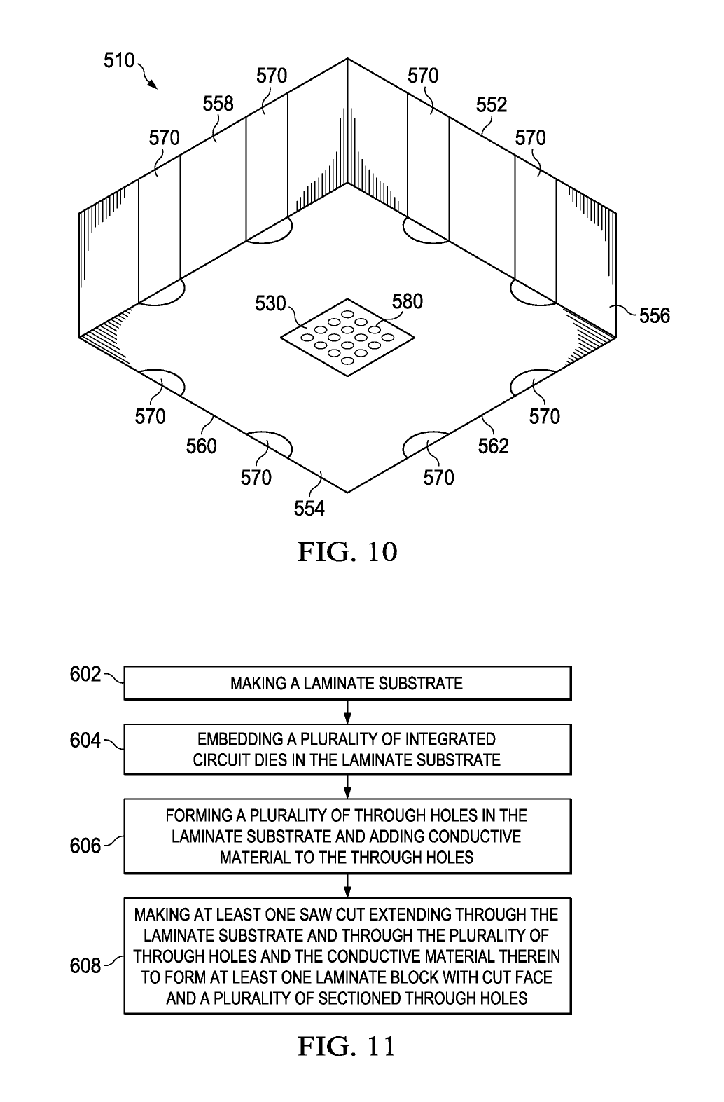

FIG. 10 is a bottom perspective view of an embedded die package 510 having a top face 552, a bottom face 554, and a plurality of side faces 556, 558, 560, 562. The package 510 has a plurality of filled sectioned through-holes 570. Alternatively, the filled sectioned through-holes 570 may be replaced by plated sectioned through-holes such as illustrated in FIG. 9. An embedded die 530 in this embodiment has a bottom surface portion configured as a ball grid array 580, which is adapted to be mounted to corresponding contact surfaces (not shown) on a top face of a printed circuit board such as board 210 illustrated in FIG. 5.

FIG. 11 is a flow chart of a method of making an electrical assembly. The method may comprise, as illustrated at 602, making a laminate substrate, and, as illustrated at 604, embedding a plurality of integrated circuit dies in the laminate substrate. The method may further include, as shown at 606, forming a plurality of through-holes in the laminate substrate and adding conductive material to the through-holes. The method may also include, as shown at 608, making at least one saw cut extending through the laminate substrate and through the plurality of through-holes and the conductive material therein to form at least one laminate block with a cut face and a plurality of sectioned through-holes.

Various embodiments of an embedded die package and of a method of making an embedded die package have been described in detail herein. Various alternative embodiments that are not expressly described herein will occur to those skilled in the art after reading this disclosure. It is intended that the appended claims be broadly construed so as to cover such alternative embodiments, except as limited by the prior art.

1. An embedded die package comprising:
a laminate block having a top face, a bottom face and a plurality of side faces extending between said top and bottom faces;
an integrated circuit die embedded in said laminate block and having a plurality of electrical contact surfaces thereon; and
at least one sectioned through-hole extending between said top and bottom faces of said laminate block, said sectioned through-hole intersecting at least one of said side faces, said sectioned through-hole containing conductive material.

2. The embedded die package of claim 1 comprising at least one circuit layer disposed between said top and bottom faces and extending generally parallel thereto, said circuit layer connecting at least one of said electrical contact surfaces on said integrated die to said conductive material in said sectioned through-hole .

3. The embedded die package of claim 1, said conductive material comprising an exposed surface portion extending from said top face to said bottom face.

4. The embedded die package of claim 1 wherein said conductive material plates said sectioned through-hole .

5. The embedded die package of claim 1 wherein said conductive material fills said sectioned through-hole .

6. The embedded die package of claim 1 wherein said face of said laminate block that is intersected by said sectioned through-hole is a sawed surface.

7. The embedded die package of claim 3 wherein said exposed surface portion of said conductive material is a sawed surface.

8. The embedded die package of claim 4 wherein said conductive material that plates said through-hole comprises at least one sawed surface.

9. An assembly comprising:
an embedded die package comprising:
a laminate block having a top face, a bottom face and a plurality of side faces extending between said top and bottom faces;
an integrated circuit die embedded in said laminate block and having a plurality of electrical contact surfaces thereon;
at least one sectioned through-hole extending between said top and bottom faces of said laminate block, said sectioned through-hole intersecting at least one of said side faces, said sectioned through-hole containing conductive material; and
at least one circuit layer disposed between said top and bottom faces and extending generally parallel thereto, said circuit layer connecting at least one of said electrical contact surfaces on said integrated die to said at least one sectioned through-hole;
a circuit board having at least one electrical contact surface on a first face thereof, wherein said embedded die package is supported on said first face of said circuit board; and
at least one solder joint bonded to said conductive material contained by said sectioned through-hole and said at least one electrical contact surface on said first face of said circuit board.

10. The assembly of claim 9 wherein said plurality of electrical contacts on said integrated circuit die comprise a plurality of contacts on a bottom face thereof and wherein said at least one electrical contact surface on said first face of said circuit board comprise a plurality of electrical contact surfaces positioned below said laminate block and connected to said plurality of contact surfaces on said bottom face of said integrated circuit die.

11. The assembly of claim 9 wherein said at least one sectioned through-hole comprises a plurality of sectioned through-holes arranged around a periphery of said laminate block; wherein said plurality of electrical contact surface on said die comprises a plurality of electrical contact surfaces connected to said plurality of sectioned through holes; wherein said at least one contact surface on said first face of said circuit board comprises a plurality of electrical contact surfaces arranged around said laminate block; and wherein said at least one solder joint comprises a plurality of solder joints connecting said plurality of sectioned through-hole s to said plurality of electrical contact surfaces on said first face of said circuit board that are arranged around said laminate block.

12. A method of making an electrical assembly comprising:
making a laminate substrate;
embedding a plurality of integrated circuit dies in the laminate substrate;
forming a plurality of through-holes in the laminate substrate and adding conductive material to the through-holes; and
making at least one saw cut extending through the laminate substrate and through the plurality of through-holes and the conductive material therein to form at least one laminate block with a cut face and a plurality of sectioned through-holes.

13. The method of claim 12 further comprising:
mounting the laminate block on a circuit board; and
making solder bonds between portions of the conductive material in the saw cut through-holes and contact surfaces on the circuit board.

14. The method of claim 12 wherein said embedding comprises embedding a flipchip die in the laminate block with a ball grid array on the flipchip die exposed at a bottom face surface of the laminate block.

15. The method of claim 12 wherein said forming a plurality of through-holes comprises forming four linear arrays of through-holes arranged in a rectangular configuration.

16. The method of claim 15 wherein said making at least one saw cut comprises making four saw cuts with each of the four saw cuts extending through one of the four linear arrays of through-holes.

17. The method of claim 12 wherein said making at least one saw cut comprises making a saw cut such that each through-hole is divided into two equal sized sectioned through-holes located in separate laminate blocks

18. The method of claim 12 wherein said adding conductive material to the through-holes comprises plating the through-holes with the conductive material.

19. The method of claim 12 wherein said adding conductive material to the through-holes comprises filling the through-holes with the conductive material.

20. The method of claim 12 wherein said making a laminate substrate comprises forming a plurality of circuit layers that extend to a peripheral portion of the laminate substrate and further comprising connecting the circuit layers to contacts on the integrated circuit die and to the conductive material in the plurality of sectioned through-holes.
